(19) United States
(12) Patent Application Publication
(10) Pub. No.: US 2005/0136656 A1
(43) Pub. Date: Jun. 23, 2005

(54) Process for depositing composite coating on a surface

(76) Inventors: Xian Ting Zeng, Singapore (SG); Xing Zhao Ding, Singapore (SG)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 11/016,117

(22) Filed: Dec. 17, 2004

(30) Foreign Application Priority Data
Dec. 19, 2003 (SG) 200307671-8

(51) Int. Cl. H01L 21/44; C23C 16/00

(52) U.S. Cl. 438/680; 118/722

(57) ABSTRACT

A method for coating a substrate surface where different types of powers are applied to the substrate and different targets. The method involves the formation of a layered structure in the coating where a metal layer is first formed, on top of which is an intermediate layer followed by a top functional layer which is chromium oxide composite. One of the power types is radio frequency power, used particularly for enhancing the efficiency of ionisation and decomposition of the reactive gases in the system. Another type of power, current that is controlled in a pulsed manner, is applied to substrate to improve the alignment of the deposited ions and atoms on the coating surface.

### TECHNICAL FIELD

This invention relates to physical and chemical vapour deposition (PVD and CVD) of a coating for a surface. More particularly, this invention relates to a method of depositing a composite coating on a substrate surface. The coating may have anti-sticking properties and thus be suitable for use on mold surfaces for plastic encapsulation of integrated circuit (IC) packages.

### BACKGROUND OF THE INVENTION

Integrated circuits (IC) are typically packaged in epoxy resins or epoxy molding compounds (EMC), which protects sensitive portions of the integrated circuits. The packaging of IC in these EMC uses IC encapsulation molds. A common problem that arises with the use of EMC is the tendency for these molding compounds to adhere to the encapsulation mold. Therefore the encapsulated IC package tends to stick to the encapsulation mold and prevents easy release of the IC packages from the encapsulation mold. Different types of EMC are used for their reliability and the stickiness of the EMC to encapsulation molds varies. As a result of the stickiness of the EMC, the encapsulation of IC can give low yield and cause frequent machine down time and can produce compromised quality of encapsulated IC packages.

To facilitate the release of encapsulated IC packages, reduce the machine down time for mold cleaning and extend tool life, it is desirable to have a mold coating with a combination of good mechanical and tribological properties. The mold coating must possess good adhesion to the mold surface, have a low friction coefficient with EMC such that it would have an excellent wear resistance and low sticking strength. These characteristics will extend mold life and reduce surface energy between the EMC and the coating, enabling ease of release of encapsulated IC packages from the IC encapsulation mold.

There are a number of methods used for depositing coatings on a mold surface. Ion plating and sputtering are such methods used. To produce ions for very dense coatings, the conventional means of producing ions includes hot filament electron beam guns, glow discharge beam guns or hollow cathode electron beam guns are used. However, these means are able to only provide ions at above 50% ionisation. A method to improve the process of ionisation by increasing ion intensity is needed to achieve a more efficient deposition of coatings. The use of a magnetic field across the electric field in the sputtering method was introduced to increase ionisation. In the patent GB2258343, a magnetron sputtering ion plating system for depositing metal ions on a substrate is disclosed. This system provides an electric field which is directed towards a substrate and a means of producing a magnetic flux in the system such that almost all electrons generated by the system are trapped in the system, thus significantly increasing ion density in the system. However, this has not been sufficient to affect the coating structure to produce dense coatings. In the publication “Study on chromium oxide synthesised by unbalanced magnetron sputtering”, Thin Solid Films 332 (1998) 295-299, the magnetron sputtering ion plating system in GB2258343 was applied. A direct current (DC) was used to apply an electric field on the substrate such that the substrate is biased with a voltage from the electric field. It was found that only a thin chromium oxide (Cr₂O₃) film was deposited with unreacted chromium in the film. From the results of this experiment, it is shown that there is a need for further improvement of coating apparatus and methods to produce dense coating which facilitate ease of release of IC packages from the IC encapsulation mold.

### SUMMARY OF THE INVENTION

The present invention provides an improved sputtering method to form a coating on a substrate surface. The coating is of a layered structure with a bonding layer, a transition interlayer and a functional layer. The method provides a biasing system where different types of power source are applied in sputtering a target for depositing the target material onto the substrate surface in the presence of a plasma. The types of power include a Direct Current (DC) power, a Radio Frequency (RF) power and a Pulsed Direct Current (PDC) power. The DC is applied to bias the target to generate ions and atomic clusters of the target material to form the bonding layer; the RF is applied to bias an electrode to improve ionisation of the plasma to form the intermediate and functional layer; and the PDC is applied to bias the substrate surface to induce alignment and growth of atoms and ions deposited on the substrate surface.

In a preferred embodiment of the present invention, an unbalanced magnetron sputtering (UMS) system is incorporated as part of the biasing system of the present invention to ensure all ions generated during the sputtering are contained in the plasma to ensure a high ion density.

The method preferably also includes supplying reactive gases.

In an embodiment of the present invention, a target for the bonding layer is selected from a group of metal consisting of chromium, titanium, tungsten and other transition metals which adhere well to the substrate surface. While the transition interlayer and the functional layer are formed from the sputtering of another target in the presence of reactive gases that are decomposed and ionised with the RF power preferably in the range of 100 W to 1200 W based on the chamber size and reactive gas flow rates used in this invention.

In another embodiment, the plasma includes an inert carrier gas and reactive gases. The reactive gases are introduced during deposition of the transition interlayer and the functional layer at a flow rate between 5 to 35 sccm, the gases may include: nitrogen(N₂), oxygen(O₂), methane (CH₄) butane(C₄H₁₀) and nitrous oxide(NO) depending on the desired transition intermediate layer. The oxygen (O₂) with methane (CH₄) or butane (C₄H₁₀) gases serve as reactive agents for forming carbon doped chromium oxides in the functional layer and the nitrogen (N₂) or nitrous oxide (NO) gas is used to form the transition layer.

In yet another embodiment, a glow discharge plasma is generated due to the influence of DC voltage applied to the target in the biased magnetron sputtering system. Preferably, the DC power applied on the target range from 2 to 3 W/cm².

Another embodiment has PDC voltage ranging from 300V to 600V at a frequency range of 100 to 300 kHz applied to the substrate surface for cleaning the surface before deposition. The PDC voltage may be varied according to the desired transition intermediate layer and functional layer which is demonstrated in the examples described in the detailed description that follows.

Another aspect of the present invention provides an apparatus for coating a substrate surface where the apparatus includes a chamber, within which a substrate holder for securing a substrate, a target, a gas inlet and an electrode are housed. The apparatus is biased by different power such that the substrate is biased with a pulse direct current (PDC), the target is biased with the direct current (DC) power; and the electrode is biased with a radio frequency (RF) power.

In a preferred embodiment, the apparatus further comprises magnets arranged in an array to form a closed magnetic field to retain ions and atomic clusters in the chamber.

Preferably, an inert carrier gas is introduced in the chamber for forming a plasma of ions and atomic clusters. More preferably, reactive gases are introduced through the gas inlet at a flow rate of 5 to 35 sccm into the chamber which are decomposed and ionised by the RF power. It is preferred that the RF is in the range of 100 W to 1200 W.

Preferably, the substrate holder is rotatable and the Pulse Direct Current (PDC) applied on the substrate range from 50V to 600V at a frequency range of 50 to 300 kHz. While the Direct Current (DC) range from 2 to 3 W/cm² .

The coating deposited in this invention demonstrates significant improvement in wear resistance and anti-sticking properties compared with existing coatings used for integrated circuit (IC) encapsulation mold. To ensure even deposition of each layer of the coating, the substrate which is secured to a substrate holder is rotated at a rate between 3 rpm -20 rpm. Each layer has a thickness determined by a duration of deposition. The thickness of the functional layer is in the range from 1.5 μm to 3 μm while the thickness of the intermediate layer is in the range of 0.3 μm-0.8 μm and the bonding layer has a thickness in the range of 0.1 μm-0.3 μm.

In forming the coating, the bonding layer is first deposited using the present method and apparatus. The DC applied to the target, is set at a range of 2 to 3 W/cm² in depositing a chromium bonding layer on the substrate surface. Reactive gases introduced through the gas inlets into the plasma are decomposed and ionised by applying the RF power through an electrode or a second target to form the transition interlayer of chromium-titanium-nitride (CrTiN). The RF power to achieve this transition interlayer is in the range of 800 W to 1200 W. The reactive gases may include: nitrogen(N₂), oxygen(O₂), methane(CH₄), butane(C₄H₁₀) and nitrous oxide(NO). The coating from the present method has a functional layer which may be formed by sputtering of the chromium target and decomposition and ionisation of Oxygen (O₂) to form a chromium oxide (Cr₂O₃) layer.

Alternatively, titanium (Ti) may be introduced in the apparatus as a second target in addition to the chromium target to form a chromium titanium oxide (Cr—Ti—O) functional layer. Preferably, the RF power applied to the titanium targets to form the functional layer is in the range from 100 to 500 W.

Preferably, the PDC power applied on the substrate surface for the deposition of chromium as the bonding layer is in the range from 100V to 150V at a frequency range of 50 Hz to 100 kHz.

Preferably, the PDC power applied to the substrate surface for the deposition of chromium nitride (CrN) as the transition interlayer range from 50V to 110 V at a frequency range from 50 kHz to 100 kHz.

It is preferred that the PDC power applied to the substrate surface for the deposition of chromium-titanium-oxide (CrTiO) as functional layer range from 50V to 130V at a frequency ranging from 50 kHz to 100 kHz.

Another coating formed by the present invention has the transition interlayer including chromium nitride (CrN), chromium nitrate (CrNO) or carbon-doped chromium-titanium-nitride(Cr—Ti—N).

In yet another coating formed by the present invention, the functional layer includes carbon doped chromium-titanium-oxide (Cr—Ti—C—O) where the sputtering includes chromium as one target and titanium as a second target in the presences of oxygen and methane or butane as reactive gases.

### BRIEF DESCRIPTION OF THE DRAWINGS

For a better understanding of the present invention and to show how it may be performed, embodiments hereof will now be described by way of non-limiting examples only, with reference to the accompanying drawings wherein:

FIG. 1 is a schematic view of an apparatus of the present invention;

FIG. 2 is a schematic view of an apparatus of a preferred embodiment of the present invention incorporating a magnetron sputtering system;

FIG. 3 is a cross-section of the layers of a coating structure produced by an embodiment of the method of the present invention.

### DETAILED DESCRIPTION OF THE INVENTION

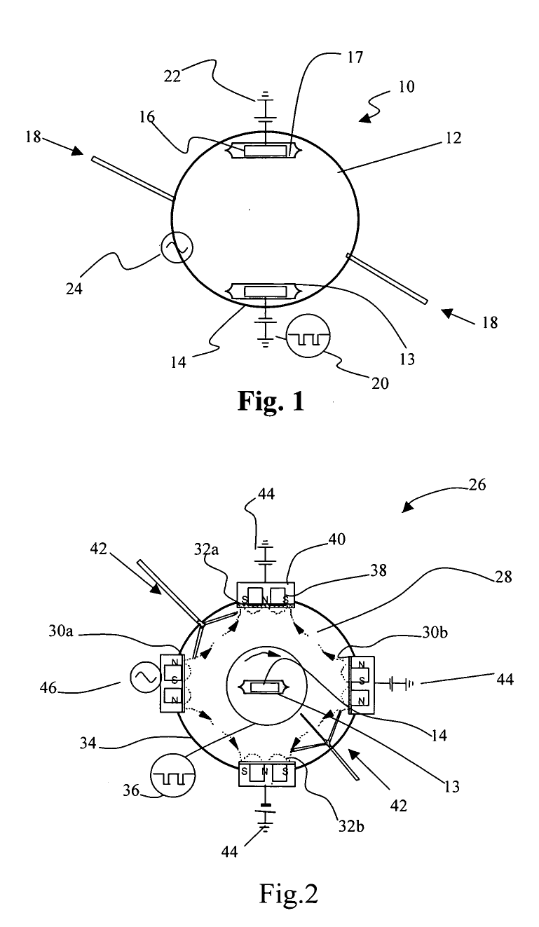

FIG. 1 schematically shows a set up of an apparatus 10 according to an embodiment of the present invention with a working chamber 12 that houses a substrate 14 secured by a substrate holder 13, a target 16 on a target holder 17 and inlets 18 for introducing reactive gases into the chamber 12 with Argon as carrier gas. The carrier gas forms a glow discharge plasma in the working chamber 12 when the Argon gas become ionised under the influence of electrical energy and radio frequency (RF) power. The electrical energy being supplied in the form of a direct current (DC) 22 voltage applied to the substrate 14 and in the form of a pulse direct current (PDC) 20 voltage applied to the target 16. While the radio frequency power (RF) 24 is applied through an electrode to the Ar plasma in the working chamber 12 where reactive gases are introduced. The biased system 10 having power applied in this configuration enables a high efficiency of ionisation. The use of DC supply enables stable formation of ions and atomic clusters sputtered from the target 16. The RF power 24 applied to the plasma provides effective decomposition of the reactive gases. The use of the PDC voltage on the substrate brings about improved quality of coating deposited as the PDC voltage provides effective ion bombardment to assist the alignment of ions and atoms on the growing coating surface. This apparatus 10 may be modified to include additional targets depending on the type of coating to be deposited. With an increase of targets, anyone of the additional targets may be used to replace the electrode for applying RF to the Ar plasma depending on the amount of sputtering required from the targets.

FIG. 2 shows the preferred embodiment where the apparatus 26 is applied with an unbalanced magnetron sputtering physical vapour deposition (UMS-PVD) system. Four targets 30a, 30b, 32a, 32b are installed at a side wall 34 of a cylindrical working chamber 28 in apparatus 26. Each target is mounted on a magnetron 40, which comprises a number of magnets 38 arranged with alternating magnetic poles arranged in series forming a continuous magnetic field to surround a substrate holder 13 on a rotatable shaft.

Before the substrate 14 is placed on the holder 13 in the working chamber 28, the substrate surface 15 is cleaned ultrasonically in alkaline solutions, rinsed and dried by blowing nitrogen gas. The substrate surface 15 is then cleaned in situ in the working chamber 28 with argon plasma by applying a pulsed direct current (PDC) power on the substrate 14 to remove surface contaminants like oxides, moisture absorption and organic contaminants.

The substrate 14 is rotated about a central axis of the holder 13. The working chamber 28 is then flushed with a carrier gas Argon (Ar), which is of high purity. The Ar is to ensure that the Ar plasma formed in the working chamber 28 will provide sufficient Ar ions for the sputtering of ions, atoms and clusters from the targets 30a, 30b, 32a and 32b. The purity of the Ar carrier gas also minimizes chemical reaction between reactive gases 42 introduced into the chamber 28 with impurities carried by the Ar carrier gas. The reactive gases 42 includes nitrogen (N₂), oxygen (O₂), nitrous oxide (N₂O₂), methane (CH₄) and butane (C₄H₁₀) which may be introduced at a controlled rate during deposition to develop a coating on the substrate 14. The holder 13 on which the substrate 14 is secured is rotated to ensure even deposition of coating on the surface 15 of the substrate 14. The thickness of the coating is determined by the time of deposition.

It is found that by applying RF power to the Ar plasma, the reactive gases are effectively ionised to form a functional layer which is a composite metal oxide as part of the coating on the substrate. By biasing the target with DC, the sputtering and ionisation of target atoms produce a constant and stable ion density in the working chamber 28. With the high density of target metal ions and ions of the reactive gases in the working chamber 28, a dense coating may be achieved. DC power is chosen to bias the target in view of the stability and ease of control. PDC power when applied to the substrate can be controlled through the frequency of the pulse while this is not possible for DC power or RF power. If DC is applied to both target(s) 30a,b and 32a,b and the substrate 14, an electric arc may be generated which may destabilise the plasma, causing damage to the power system and giving poor coating quality. In view that RF power is more unstable and hence more difficult to control, it was not used as the biasing power for the substrate 14. It was found that PDC was suitable for biasing the substrate 14 as this form of power source can be effectively controlled to grow and realign the ions or atoms on the substrate surface and thus improve the coating quality. RF power is applied to the plasma to enable the molecules of reactive gases to decompose into atomic ions and form the functional layer of the coating on the substrate 14. RF may be applied to decompose and ionise the reactive gases in the Ar plasma through one of the targets or with an additional electrode. The target from which less ions are desired is usually selected to act as an electrode for the RF power. Together with the magnetic field provided by the UMS-PVD system, the ions generated with the aid of the applied powers are contained in the working chamber 28 thus improving the ion density and hence the coating density.

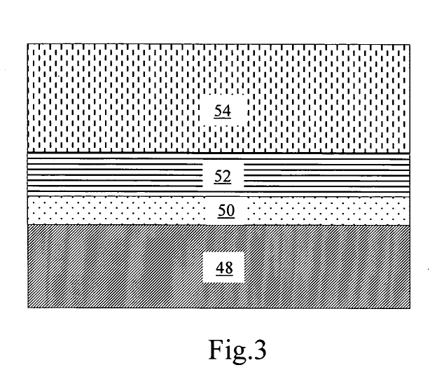

FIG. 3 shows the coating design on the substrate surface. The substrate surface 48 is first coated with a metal bonding layer 50, using the biased unbalanced magnetron sputtering system (UMS-PVD) 26. A graded transition interlayer 52 is formed on top of this metal bonding layer 50. The graded transition interlayer 52 may comprise of a number of metal alloy nitride layers. A third functional layer 54 is formed on top of the graded transition interlayer 52. This functional layer 54 is a metal oxide composite. The thickness of this functional layer range from 1.51 μm to 3 μm while the thickness of the intermediate layer is in the range of 0.3 μm-0.8 μm and the bonding layer has a thickness in the range of 0.1 μm-0.3 μm.

The following example is used to illustrate the formation of these layers with the present method.

### EXAMPLE

In the following example, a number of polished high-speed steel disks of 50 mm in diameter and 6 mm in thickness were used as substrates for deposition of coating samples to determine the characteristics of the coating by the current method. The pressure in the working chamber 28 was pumped down to below 1×10⁻⁵ Torr and each substrate was ultrasonically cleaned, followed by in situ Ar plasma cleaning with a pulse direct current (PDC) bias of −400 V and 300 kHz applied on the substrate for 10 to 30 minutes. Although the argon (Ar) gas flow during the deposition was set at a rate of 10 sccm, it can be varied. The substrate is rotated on the holder at a rate of 3-10 rpm and the substrate temperature is raised to a range between 150° C. and 300° C. by plasma bombardment, depending on the deposition time and the powers applied to the target and substrate.

According to the illustration in FIG. 2, chromium and titanium metal are used as targets 30a, 30b, 32a, and 32b. The targets are biased with direct current (DC) power while one of the targets is biased with radio frequency (RF) power. The substrate 14 is biased with pulsed direct current (PDC) power. The DC power applied to the chromium targets is 2 to 3 W/cm². The RF power applied on the titanium targets and the pulse DC applied on the substrate is set out in Table 1 below.

TABLE 1

| RF Power applied on titanium target to form: - | |
|---|---|
| CrTiN layer | RF 1000 W |
| CrTiCO functional layer | RF 300 W |
| Pulse Direct Current power applied on Substrate for forming: - | |
| Cr bond layer | 110 V at 50 kHz |
| CrN transition layer | 60 V at 50 kHz |
| Cr—Ti—C—O functional layer | 60-110 V at 50 kHz |

The chromium targets 30a, 30b have DC power applied thereto for sputtering to generate chromium atoms, ions and atomic clusters for coating deposition on the substrate surface 48. During the deposition of an optional graded transition chromium titanium nitride (CrTiN) supporting layer 52, RF power is applied to the titanium target to provide decomposition and ionization enhancement of the reactive gases 42. During deposition of the functional layer 54, PDC power is applied to the substrate 14 to induce growth and alignment of the ions deposited on the substrate surface 48. Having the targets 30a, 30b, 32a, 32b biased with the respective power configuration provides flexibility and efficiency to control the plasma density and the ion energy. It was found that during deposition of the functional layer 54 of the present invention, the substrate 14 has a bias current which is significantly higher than that in the unbalanced magnetron sputtering system described in the UK patent GB2258343.

From this significant increase in the bias current in the experimental results, it is shown that the application of RF power increase ion bombardment density on the growing coating surface.

It is to be appreciated by any one skilled in the art that the above description of present invention is to be considered as illustrative and is not restricted to or limited to the embodiments. Modifications may be made to the invention as shown in the specific embodiments without departing from the scope and the spirit of the invention where such embodiments provide advantages complimentary to those already described.

1. A method of sputter deposition of a thin film coating on a substrate surface comprising:
providing a target;
supplying an inert gas to establish a plasma within which the target and the substrate are contained;
supplying a radio frequency (RF) power to the plasma for providing ions for bombarding the target and the substrate surface;
applying a direct current (DC) voltage to the target to sputter target materials of atomic scale for deposition on the substrate surface;
applying a pulse direct current (PDC) voltage to the substrate to induce alignment and growth of deposited materials on the substrate surface.

2. The method according to claim 1 includes trapping of ions in the plasma within a magnetic field.

3. The method according to claim 1 includes supplying reactive gases to the plasma, wherein the reactive gases are ionised by the radio frequency power supplied to the plasma to form materials of atomic scale.

4. The method according to claim 3, includes deposition of the materials of atomic scale formed from ionised reactive gases on the substrate surface as dopants in the coating.

5. The method according to claim 4, wherein the reactive gases are introduced at a flow rate between 5 to 30 sccm.

6. The method according to claim 1, wherein the plasma is a glow discharge plasma generated by the direct current voltage.

7. The method according to claim 6, wherein the direct current voltage applied on the target range from 2 to 3 W/cm².

8. The method according to claim 1, wherein the pulse direct current voltage applied to the substrate surface range from 50V to 600V at a frequency range of 50 to 300 kHz.

9. The method according to claim 1, wherein the RF power is in the range of 100 W-1200 W.

10. The method according to claim 1 includes rotating the substrate at a rate between 3-10 rpm.

11. The method according to claim 1, wherein the thin film coating has a thickness determined by duration of deposition.

12. The method according to claim 1 includes sputtering at least one target for the deposition of multiple thin films layers on a single substrate, wherein the multiple thin film layers include a bonding layer, a transition interlayer and a functional layer.

13. The method according to claim 12, wherein the transition interlayer and the functional layer is sputtered in the presence of reactive gases introduced to the plasma and ionised by the radio frequency (RF) power to form materials of atomic scale.

14. The method according to claim 13, wherein the reactive gases are selected from a group consisting of nitrogen (N₂), oxygen (O₂), methane (CH₄), butane (C₄H₁₀) and nitrous oxide (NO).

15. The method according to claim 13, wherein the functional layer has a thickness that range from 1.5 μm to 3 μm.

16. The method according to claim 12, wherein the deposition of chromium as the bonding layer results from sputtering of a chromium target with the PDC voltage applied to the substrate ranging from 100V to 150V at a frequency of 50 Hz to 100 kHz.

17. The method according to claim 14, wherein the deposition of chromium nitride as the transition interlayer resulting from sputtering a chromium target while applying PDC voltage to the substrate at a range from 50V to 110 V and at a frequency ranging from 50 kHz to 100 kHz.

18. The method according to claim 14, wherein the deposition of chromium-titanium-oxide as functional layer resulting from sputtering chromium and titanium targets while applying PDC power to the substrate surface at a range from 50V to 130V and at a frequency ranging from 50 kHz to 100 kHz.

19. The method according to claim 14, wherein the deposition of the transition interlayer results from sputtering of multiple targets consisting of chromium and titanium to form chromium-titanium-nitride.

20. The method according to claim 14, wherein the deposition of the transition interlayer results from sputtering of a chromium target to form at least one from a group consisting of chromium nitride and chromium carbonitride.

21. The method according to claim 16, wherein the deposition of chromium-titanium-nitride as transition interlayer includes having the RF power in the range of 800 W to 1200 W.

22. The method according to claim 14, wherein the deposition of the functional layer results from the sputtering of a chromium target to form of at least one of a group consisting of carbon-doped chromium oxide (Cr—C—O) and chromium titanium oxide (Cr—Ti—C—O).

23. The method according to claim 20, wherein the deposition of chromium titanium oxide (Cr—Ti—C—O) as functional layer includes having titanium as a target and the RF power in the range of 100 W to 500 W.

24. A sputter deposited thin film coating on a substrate surface comprising a bonding layer, a transition interlayer, and a functional layer, wherein the functional layer is selected from a group consisting of carbon-doped chromium oxide (Cr—C—O) and chromium titanium oxide(Cr—Ti—C—O).

25. An apparatus for sputter deposition of a thin film coating on a substrate surface, the apparatus comprising:
a chamber having a substrate holder for securing a substrate and a target holder for securing a target within the chamber;
an inlet for supplying gas into the chamber;
a pulsed direct current power supply for applying a pulsed direct current (PDC) voltage to bias the substrate;
a direct current power supply for applying a direct current (DC) voltage to bias the target; and
an energy supply, including a radio frequency (RF) power, for applying energy to the gas;
wherein:
the direct current (DC) power is supplied to generate materials of atomic scale from the target; and
the pulsed direct current (PDC) power is supplied to induce alignment and growth of materials of atomic scale deposited on the substrate surface;
the energy supply is provided to the gas to form a plasma within the chamber.

26. The apparatus of claim 25, wherein the apparatus comprises magnets arranged in an array to form a closed magnetic field to retain ions and atomic clusters in the chamber.

27. The apparatus of claim 25, wherein the substrate holder is rotatable.

28. The apparatus of claim 25, wherein the target is selected from a group of metals.

29. The apparatus of claim 28, wherein the target is selected from a group consisting of titanium, chromium and tungsten.

30. The apparatus of claim 25, wherein the inlet has a flow rate of 5 to 35 sccm for the gas introduced into the chamber.

31. The apparatus of claim 25, wherein the gas is an inert gas.

32. The apparatus of claim 25, wherein the gas includes reactive gases selected from a group consisting of nitrogen, oxygen, methane, butane and nitrous oxide.

33. The apparatus of claim 32, wherein the RF power is used to increase ionisation of the reactive gases.

34. The apparatus of claim 25, wherein the pulse direct current (PDC) voltage range from 50V to 600V at a frequency range of 50 to 300 kHz.

35. The apparatus of claim 25, wherein the direct current (DC) voltage range from 2 to 3 W/cm².

36. The apparatus of claim 25, wherein the RF power is in the range of 100 W to 1200 W.

37. The apparatus of claim 25 wherein the sputter deposited thin film coating has a functional layer selected from a group consisting of carbon-doped chromium oxide (Cr—C—O) and chromium titanium oxide(Cr—Ti—C—O).
